(19) United States
(12) Patent Application Publication
(10) Pub. No.: US 2019/0119533 A1
(43) Pub. Date: Apr. 25, 2019

(54) ELECTRICALLY CONDUCTIVE ADHESIVE FOR CONNECTING CONDUCTORS TO SOLAR CELL CONTACTS

(71) Applicant: Heraeus Deutschland GmbH & Co. KG, Hanau (DE)

(72) Inventors: Daniel HANSELMANN, Gelnhausen (DE); Tanja DICKEL, Neuberg (DE); Alexander BRAND, Elsenfeld (DE); Sebastian FRITZSCHE, Hanau (DE); Markus KOENIG, Dieburg (DE)

(21) Appl. No.: 16/217,252

(22) Filed: Dec. 12, 2018

Related U.S. Application Data
(63) Continuation of application No. 15/542,778, filed on Jul. 11, 2017.

(30) Foreign Application Priority Data
Jan. 12, 2015 (EP) 15150720.9

(51) Int. Cl. C09J 9/02; H01L 31/05; C08G 59/50; C09J 163/00; H01B 1/22

(52) U.S. Cl. CPC C09J 9/02; H01L 31/0512; C08G 59/50; C08K 2003/0806; H01B 1/22; H01L 31/0516; C09J 163/00

(57) ABSTRACT

An electrically conductive composition as an electrically conductive adhesive for mechanically and electrically connecting at least one contact of a solar cell with an electrical conductor is provided. The contact is selected from emitter contacts and collector contacts and the electrically conductive composition contains (A) 2 to 35 vol.-% silver particles having an average particle size of 1 to 25 μm and exhibiting an aspect ratio in the range of 5 to 30:1, (B) 10 to 63 vol.-% non-metallic particles having an average particle size of 1 to 25 μm and exhibiting an aspect ratio in the range of 1 to 3:1, (C) 30 to 80 vol.-% of a curable resin system, and (D) 0 to 10 vol.-% of at least one additive, in which the sum of the vol.-% of particles (A) and (B) totals 25 to 65 vol.-%.

### CROSS-REFERENCE TO RELATED APPLICATIONS

This application is a Section 371 of International Application No. PCT/EP2015/077745, filed Nov. 26, 2015, which was published in the English language on Jul. 21, 2016 under International Publication No. WO 2016/113026 A1 and the disclosure of which is incorporated herein by reference.

### BACKGROUND OF THE INVENTION

The invention relates to the use of an electrically conductive composition as an electrically conductive adhesive for mechanically and electrically connecting electrical conductors to electrical contacts of solar cells.

Solar cells can convert light, such as sunlight, into electrical energy. It is possible to collect the electrical energy from one single solar cell. In order to increase the voltage delivered by individual solar cells to a suitable level, a plurality of solar cells is conventionally electrically connected together in series to form an array of solar cells which can be incorporated into a photovoltaic module. Collection of the electrical energy and electrical connection of solar cells is typically made via electrical conductors which are mechanically and at the same time electrically connected to the emitter and collector contacts of the solar cells. The simultaneous mechanical and electrical connection of the electrical conductors to the cell contacts is typically made by soldering or by adhesive bonding, in the latter case making use of an electrically conductive adhesive.

The term “electrical conductor” used herein means conventional electrical conductors such as, for example, conventional wire, tape, ribbon or conductive backsheet foil (back contacting foil).

The term “emitter contact” used herein means an electrical contact connecting the emitter of a solar cell to an electrical conductor, whereas the term “collector contact” used herein means an electrical contact connecting the collector of a solar cell to an electrical conductor. The electrical contacts take the form of metallizations.

In most of today's photovoltaic modules, the solar cells have emitter contacts and collector contacts located on opposite sides of the cells. The emitter contacts are located on the front surface, i.e., the surface exposed to the sunlight, whereas the collector contacts are on the back side. An example are H-type cells, typically having two emitter contacts known as emitter busbars on their front face and two collector contacts also known as collector busbars on their back face. A skilled person will recognize that emitter contacts and collector contacts are of opposite polarity.

New cell types have been developed in which the emitter contacts have been moved from the front face to the back face of the solar cell in order to free up an additional portion of front surface and increase the amount of electrical energy that can be produced by the cell. Such solar cells, in which both emitter and collector contacts are located on the back side of the cell, are known under the common designation “back-contact cells,” which designation includes metallization wrap-through (MWT) cells, back-junction (BJ) cells, integrated back-contact (IBC) cells and emitter wrap-through (EWT) cells. In the case of these back-contact cells, the emitter contacts are the so-called “vias,” or “back emitter contacts,” located on the back face of the cells, while the collector contacts are also located there.

Most of today's solar cells are silicon solar cells.

Conventional electrically conductive adhesives comprise a huge portion of silver particles with an order of magnitude of about 80 wt.-% (weight-%). Because of the high silver price, so-called low-silver alternatives have been developed to replace a considerable portion of the silver particles with silver-coated particles, for example, silver-coated copper particles. However, there are concerns to using such a type of copper containing electrically conductive adhesive for the adhesive bonding of electrical conductors to solar cell contacts, in particular in the case of silicon solar cells. The reasoning is that solar cells are intended for long-term use, which enlarges the risk that during a solar cell's service life copper diffuses into the solar cell bulk material and hence forms undesired efficiency reducing recombination centers or even destroys the p-n or n-p transition of the solar cell. This is in particular a concern in the case of silicon solar cells. However, these concerns apply not only in the case of copper but also in the case of other elements having a similar effect like copper. Examples of such elements include phosphorus, titanium, vanadium, chromium, manganese, iron, cobalt, nickel, zirconium, niobium, molybdenum, tantalum and tungsten, see “Energy research Centre of the Netherlands, Gianluca Coletti, Sensitivity of crystalline silicon solar cells to metal impurities, Sep. 14, 2011” or “J. R. Davis in IEEE Trans El. Dev. ED-27, 677 (1980)”.

### BRIEF SUMMARY OF THE INVENTION

The invention relates to an electrically conductive composition as an electrically conductive adhesive for mechanically and electrically connecting at least one contact of a solar cell, preferably a silicon solar cell, with an electrical conductor, wherein the contact is selected from the group consisting of emitter contacts and collector contacts. The electrically conductive composition comprises:
(A) 2 to 35 vol.-% (volume-%) of silver particles having an average particle size in the range of 1 to 25 μm and exhibiting an aspect ratio in the range of 5 to 30:1,
(B) 10 to 63 vol.-% of non-metallic particles having an average particle size in the range of 1 to 25 μm, exhibiting an aspect ratio in the range of 1 to 3:1,
(C) 30 to 80 vol.-% of a curable (hardenable, crosslinkable) resin system, and
(D) 0 to 10 vol.-% of at least one additive, wherein the sum of the vol.-% of particles (A) and (B) totals 25 to 65 vol.-%.

### DETAILED DESCRIPTION OF THE INVENTION

The invention prevents the risks described above by using a specific electrically conductive low-silver type adhesive for mechanically and at the same time electrically connecting the contacts of a solar cell with electrical conductors. In an embodiment, the elements copper, phosphorus, titanium, vanadium, chromium, manganese, iron, cobalt, nickel, zirconium, niobium, molybdenum, tantalum, aluminum and tungsten in elemental or metal form or in the form of an alloy are essentially or completely avoided in the electrically conductive adhesive.

In the description and the claims the term “solar cell” is used. It shall not mean any limitation as to a certain type of solar cell. It includes any type of solar cell including, in particular, silicon solar cells. The cells may be of the afore mentioned H- or back-contact cell type, for example.

In an embodiment, the sum of the vol.-% of (A), (B), (C) and, if present, (D) may total 100 vol.-% of the electrically conductive composition.

The vol.-% disclosed in the description and the claims refers to the electrically conductive composition, i.e., not yet cured, or, to be even more precise, to the electrically conductive composition prior to its application or use according to the invention.

In the description and the claims, the term “average particle size” is used. It shall mean the mean primary particle diameter (d₅₀) determined by laser diffraction. Laser diffraction measurements can be carried out making use of a particle size analyzer, for example, a Mastersizer 3000 from Malvern Instruments.

In the description and the claims, the term “aspect ratio” is used with regard to the shape of the particles (A) and (B) included in the electrically conductive composition. The aspect ratio means the ratio of the largest dimension to the smallest dimension of a particle and it is determined by SEM (scanning electron microscopy) and evaluating the electron microscopical images by measuring the dimensions of a statistically meaningful number of individual particles.

The electrically conductive composition comprises 2 to 35 vol.-%, preferably 2 to 30 vol.-% and most preferably 2 to 20 vol.-% of silver particles (A) having an average particle size in the range of 1 to 25 μm, preferably 1 to 20 μm, most preferably 1 to 15 μm and exhibiting an aspect ratio in the range of 5 to 30:1, preferably 6 to 20:1, most preferably 7 to 15:1. The silver particles (A) may have a coating comprising at least one organic compound, in particular a C8 to C22 fatty acid or derivative thereof like salts or esters. The vol.-% values include the volume contribution of said coatings on the silver particles (A).

The silver particles (A) include particles of silver and silver alloys; i.e., the term “silver particles” used herein shall mean particles of pure silver and/or of silver alloy. In the case of silver alloy, the total proportion of alloying metals is, for example, >0 to 5 wt.-%, preferably >0 to 1 wt.-%. The silver alloys may comprise binary alloys of silver and one other metal or alloys of silver with more than one metal other than silver. Examples of metals which can be used as alloying metals for the silver include, in particular, zinc, rhodium, palladium, indium, tin, antimony, rhenium, osmium, iridium, platinum, gold, lead and bismuth. In an embodiment, copper, phosphorus, titanium, vanadium, chromium, manganese, iron, cobalt, nickel, zirconium, niobium, molybdenum, tantalum, aluminum and tungsten are excluded as alloying elements.

The silver particles (A) exhibit an aspect ratio in the range of 5 to 30:1, preferably 6 to 20:1, most preferably 7 to 15:1. This aspect ratio expresses that the silver particles (A) are, for example, acicular particles (needles) or flakes (platelets) as opposed to, for example, particles having a spherical, an essentially spherical, an elliptical or an ovoid shape.

The electrically conductive composition may comprise one type of silver particles (A) or a combination of two or more different types of silver particles (A). In any case, all types of silver particles (A) contained in the electrically conductive composition meet the afore mentioned average particle size and aspect ratio conditions. To illustrate this, the following theoretical example may be envisaged: An electrically conductive composition may comprise two different types of silver particles as the only particles (A), namely X vol.-% of silver particles having a d50 value of x μm and an aspect ratio of y:1, and Y vol.-% of silver particles having a d50 value of v μm and an aspect ratio of w:1, with X+Y lying in the 2 to 35 vol.-% range, x and v independently lying in the 1 to 25 μm range and y and w independently lying in the 5 to 30:1 range.

Silver particles of type (A) are commercially available. Examples of such silver particles include SF-3, SF-3J from Ames Goldsmith; Silver Flake #80 from Ferro; and RA-0101, AA-192N from Metalor.

In an embodiment, the electrically conductive composition may comprise a portion, for example, 10 to 30 vol.-%, of silver particles other than those of type (A), in particular, silver particles having an aspect ratio in the range of, for example, 1 to <5:1 or 1 to 3:1. One commercially available example of such silver particles is FA-3162 from Metalor.

The electrically conductive composition comprises 10 to 63 vol.-%, preferably 15 to 63 vol.-% and most preferably 15 to 60 vol.-% of non-metallic particles (B) having an average particle size in the range of 1 to 25 μm, preferably 1 to 20 μm, most preferably 1 to 15 μm, and exhibiting an aspect ratio in the range of 1 to 3:1, preferably 1 to 2:1, most preferably 1 to 1.5:1. Examples of useful particles of the (B) type include graphite particles and electrically non-conductive non-metallic particles, in each case meeting these average particle size and aspect ratio conditions. The term “electrically non-conductive non-metallic particles” used herein shall mean non-metallic particles of a material having an electrical conductivity of <10⁻⁵ S/m. Examples of such materials include glass, ceramics, plastics, diamond, boron nitride, silicon dioxide, silicon nitride, silicon carbide, aluminosilicate, aluminum oxide, aluminum nitride, zirconium oxide and titanium dioxide.

The non-metallic particles (B) exhibit an aspect ratio in the range of 1 to 3:1, preferably 1 to 2:1, most preferably 1 to 1.5:1. This aspect ratio expresses that the particles (B) have a true spherical or essentially spherical shape as opposed to particles like, for example, acicular particles or flakes. The individual particles (B) when looked at under an electron microscope have a ball like or near-to-ball like shape, i.e., they may be perfectly round or almost round, elliptical or they may have an ovoid shape.

The electrically conductive composition may comprise one type of particles (B) or a combination of two or more different types of particles (B). In any case, all types of particles (B) contained in the electrically conductive composition meet the afore mentioned average particle size and aspect ratio conditions.

Particles of type (B) are commercially available. Examples include AE9104 from Admatechs; EDM99,5 from AMG Mining; CL4400, CL3000SG from Almatis; Glass Spheres from Sigma Aldrich; Spheromers® CA6, CA10, CA15 from Microbeads®.

In a preferred embodiment, the silver particles (A) have an average particle size in the range of 0.2 to 2 times the average particle size of the non-metallic particles (B).

The sum of the vol.-% of silver particles (A) and non-metallic particles (B) totals 25 to 65 vol.-%.

The electrically conductive composition comprises 30 to 80 vol.-%, preferably 30 to 75 vol.-% and most preferably 30 to 70 vol.-% of a curable resin system (C).

The curable resin system (C) comprises those constituents of the electrically conductive composition which, after the application and curing thereof, form a covalently crosslinked polymer matrix in which the (A) and (B) particles are embedded.

“Curable resin system” means a resin system comprising at least one self-crosslinkable resin, typically in combination with a starter or initiator, and/or one or more crosslinkable resins in combination with one or more hardeners (crosslinkers, curing agents) for the one or more crosslinkable resins. However, the presence of non-reactive resins within such a curable resin system is also possible. To avoid misunderstandings, the term “resin system,” although generally understood as referring to polymeric materials, shall not be understood as excluding the optional presence of oligomeric materials. Oligomeric materials may include reactive thinners (reactive diluents). The border between oligomeric and polymeric materials is defined by the weight average molar mass determined by gel permeation chromatography (GPC; divinylbenzene-crosslinked polystyrene as the immobile phase, tetrahydrofuran as the liquid phase, polystyrene standards). Oligomeric materials have a weight average molar mass of ≤500, while the weight average molar mass of polymeric materials is >500.

Typically, the constituents of the curable resin system (C) are non-volatile; however, volatile compounds which can be involved in the curing mechanism of the curable resin system may also be present.

The curable resin system (C) is curable by formation of covalent bonds. Covalent bond forming curing reactions may be free-radical polymerization, condensation and/or addition reactions, wherein condensation reactions are less preferred.

As has already been mentioned, the curable resin system (C) comprises those constituents of the electrically conductive composition which, after the application and curing thereof, form a covalently crosslinked polymer matrix or polymer network. This polymer matrix may be of any type, i.e., it may comprise one or more polymers or one or more hybrids of two or more different polymers. Examples of possible polymers may include (meth)acryl copolymers, polyesters, polyurethanes, polysiloxanes, polyethers, epoxy-amine-polyadducts and any combinations. The polymers forming this polymer matrix may stem from polymeric components of the curable resin system (C) and/or may be formed during polymer forming curing reactions of the curable resin system (C) after application and during curing of the electrically conductive composition.

Hence, the one or more resins which may be constituents of the curable resin system (C) may be selected from, for example, (meth)acryl copolymer resins, polyester resins, polyurethane resins, polysiloxane resins, polyether resins including epoxy resin type polyether resins, epoxy-amine-polyadducts and hybrids thereof.

Self-crosslinkable resins of the curable resin system (C) may be resins carrying functional groups capable of reacting among themselves under formation of covalent bonds in the sense of crosslinked network formation. In the alternative, self-crosslinkable resins are resins carrying different functional groups (F1) and (F2) in one and the same molecule, wherein the functional groups (F2) exhibit a reactive functionality complementary to the functionality of the functional groups (F1). The combination of a crosslinkable resin with a hardener means that the crosslinkable resin carries functional groups (F1), while the hardener carries other functional groups (F2) exhibiting a reactive functionality complementary to the functionality of the functional groups (F1). Examples of such complementary functionalities (F1)/(F2) are: carboxyl/epoxy, hydroxyl/isocyanate, epoxy/amine, free-radically polymerizable olefinic double bond/free-radically polymerizable olefinic double bond and the like. The reaction of the complementary functionalities (F1)/(F2) leads in any case to the formation of covalent bonds with the result of forming a covalently crosslinked polymer network.

In a preferred embodiment, the curable resin system (C) comprises a self-crosslinkable epoxy resin or a system of epoxy resin and hardener for the epoxy resin selected among polyamine hardeners, polycarboxylic acid hardeners and polycarboxylic acid anhydride hardeners. The system of epoxy resin and polyamine hardener for the epoxy resin may optionally comprise lactone.

A curable resin system (C) comprising a self-crosslinkable epoxy resin may comprise a starter or an initiator. It may be a cationically curable system. To initiate cationic cure, it requires a cationic initiator, which may be thermo- or UV-labile. Hence, a cationically curable resin system (C) comprising a self-crosslinkable epoxy resin may be a thermally curable or a UV-curable resin system.

Examples of useful epoxy resins are bisphenol A and/or bisphenol F epoxy resins, novolac epoxy resins, aliphatic epoxy resins and cycloaliphatic epoxy resins. Examples of such commercially available epoxy resins include Araldite® GY 279, Araldite® GY 891, Araldite® PY 302-2, Araldite® PY 3483, Araldite® GY 281 and Quatrex® 1010 from Huntsman; D.E.R.™ 331, D.E.R.™ 732, D.E.R.™ 354 and D.E.N™ 431 from Dow Chemical; JER YX8000 from Mitsubishi Chemical; and EPONEX™ Resin 1510 from Momentive Specialty Chemicals.

Examples of useful polyamine hardeners are compounds comprising more than one primary or secondary amino group per molecule. Typical examples are diamines, triamines and other polyamines with at least two amino groups in the molecule, wherein the amino groups are selected from primary and secondary amino groups. Secondary amino groups can be present as lateral or terminal functional groups or as member of a heterocyclic ring. Examples of preferred polyamine hardeners include diethylenetriamine, ethylenediamine, triethylenetetramine, aminoethylpiperazine and Jeffamine® D230 from Huntsman.

Examples of useful polycarboxylic acid hardeners include methylhexahydrophthalic acid and their possible anhydrides.

An example of a useful cationic initiator is 1-(p-methoxybenzyl) tetrahydrothiophenium hexafluoroantimonate.

Examples of useful lactones are delta-valerolactone, delta-hexalactone, delta-nonalactone, delta-decalactone, delta-undecalactone, gamma-butyrolactone, gamma-hexalactone, gamma-heptalactone, gamma-octalactone, epsilon-caprolactone, epsilon-octalactone, epsilon-nonalactone and mixtures thereof

The electrically conductive composition comprises 0 to 10 vol.-% of at least one additive (D).

Examples of additives include 4-cyclohexanedimethanol divinylether; organic solvents, for example, isopropanol, n-propanol, terpineol; wetting agents, for example, oleic acid; rheological modifiers, for example, nanosized silica, ethylcellulose.

So far, the composition of the electrically conductive composition has been looked at vol.-%-wise. In an embodiment, the electrically conductive composition comprises 15 to 60 wt.-% of the silver particles (A), 10 to 75 wt.-% of the non-metallic particles (B), 7 to 35 wt.-% of the curable resin system (C), and (D) 0 to 5 wt.-% of the at least one additive, wherein the sum of the wt.-% of (A) and (B) totals 60 to 93 wt.-% and wherein the sum of the wt.-% of (A), (B), (C) and, if present, (D) may total 100 wt.-% of the electrically conductive composition. The wt.-% disclosed in the description and the claims refer to the electrically conductive composition, i.e., not yet cured, or to be even more precise, to the electrically conductive composition prior to its use according to the invention.

Preferably, the viscosity of the electrically conductive composition is in the range of 4 to 45 Pa·s, most preferably 8 to 35 Pa·s, measured in accordance with DIN 53018 (at 23° C., CSR-measurement, cone-plate system, shear rate of 50 rounds per second).

The electrically conductive composition can be made by mixing components (A), (B), (C) and, optionally, (D), wherein it is preferred to introduce component (C) first before adding components (A) and (B). After completion of the mixing, the so-produced electrically conductive composition can be stored until its use according to the invention. It may be advantageous to store the electrically conductive composition at low temperatures of, for example, −78 to +8° C.

Depending on the chemical nature of the (C) component and if desired or expedient, it is also possible to split component (C) into sub-components, for example, into a curable resin sub-component (C1) and a hardener sub-component (C2) and to mix (A), (B), (C1) and, optionally, (D) and store that mixture separately from (C2). In so doing, a two-component type of the electrically conductive composition is obtained. Its two components are stored separately from each other until the electrically conductive composition is used according to the invention. The two components are then mixed shortly or immediately before the application.

The electrically conductive composition is used according to the invention, i.e., it is used as an electrically conductive adhesive for mechanically and—at the same time—electrically connecting at least one contact of a solar cell with an electrical conductor, wherein the at least one contact is selected from the group consisting of solar cell emitter contacts and solar cell collector contacts.

To this end, the electrically conductive composition is applied to the contact surface of the at least one contact of the solar cell and/or to the contact surface of the electrical conductor to be adhesively bonded to the at least one contact of the solar cell. Typically, the contact surface of a solar cell's contact is a metallization as has already been afore mentioned in the paragraph explaining emitter and collector contacts. The contact surface of an electrical conductor may be a terminal and/or other suitable place of a wire, tape or ribbon. In case of an electrical conductor in the form of a conductive back sheet foil the contact surface thereof is typically in the form of a pattern designed to fit the at least one contact of the solar cell.

Application of the electrically conductive composition may be performed, for example, by printing, e.g., screen printing or stencil printing, by jetting or by dispensing. The typical thickness of the applied and uncured electrically conductive composition lies in the range of, for example, 20 to 500 μm.

After the application of the electrically conductive composition, the one or more solar cell contacts and the electrical conductor(s) to be adhesively bonded thereto are put together with their contact surfaces having the electrically conductive composition in between.

Before the curing, i.e., after the application and prior to or after putting together the one or more solar cell contacts and the electrical conductor(s), an optional drying step may be performed in order to remove eventually present volatile compounds like, for example, organic solvent, from the electrically conductive composition. If such a drying step is performed, the drying parameters are for example, 1 to 120 minutes at an object temperature of, for example, 60 to 160° C.

The so formed assembly comprising the electrically conductive composition is then cured, i.e., the electrically conductive composition is cured. Curing may be initiated by UV irradiation if at least one of the contact surfaces to be adhesively bonded is sufficiently transparent for UV-light and/or allows sufficient access of UV-light and if the curing chemistry of the (C) system allows for UV curing. Examples of UV-curable (C) systems are the already mentioned curable resin system (C) comprising a self-crosslinkable epoxy resin and a UV-labile cationic initiator or a curable resin system (C) comprising free-radically polymerizable components and a UV-labile free-radical initiator. In the more common alternative of thermal curing, heat is applied and the assembly including the electrically conductive composition is heated, for example, for 5 to 30 minutes at an object temperature of, for example, 80 to 160° C. Thermal curing may be performed in a separate step or may take place in the course of assembling and consolidating a photovoltaic module or photovoltaic stack as will be disclosed below in more detail.

In the hardened state the electrically conductive composition is solid.

After completion of the curing, the solar cell with the electrical conductors attached to its contacts or the array of solar cells connected to each other by electrical conductors may be used for the production of electrical energy, or, in particular, it may be incorporated into a conventional photovoltaic module. To this end, a photovoltaic stack or photovoltaic module may be assembled, for example, by placing a conventional back encapsulant layer on a conventional back sheet, placing the solar cell or the array of solar cells on top of the back encapsulant layer, placing a conventional front encapsulant layer on top of the one or more solar cells and then placing a conventional front sheet on top of the front encapsulant layer. Typically, a so-assembled photovoltaic stack is then consolidated in a laminating device by heating the stack and subjecting the heated photovoltaic stack to a mechanical pressure in a direction perpendicular to the plane of the stack and decreasing the ambient pressure in the laminating device. The heating allows the front and back encapsulants to soften, flow around and adhere to the one or more solar cells and, if not yet performed, to thermally cure the electrically conductive composition; i.e., in the latter case the thermal curing takes place during the consolidation of the photovoltaic stack. Finally, the photovoltaic stack is cooled to ambient temperature and the mechanical pressure is released and atmospheric pressure is reestablished in the laminating device.

### EXAMPLES

### Example 1a

### Preparation of an Electrically Conductive Composition

A mixture of components of type (C) and (D) was made by mixing 69 pbw (parts by weight) of Araldite® PY 302-2 from Huntsman, 4 pbw of 1-(p-methoxybenzyl) tetrahydrothiophenium hexafluoroantimonate, 21 pbw Araldite® DY-E (reactive diluent) from Huntsman, and 6 pbw of oleic acid.

13 vol.-% (40 wt.-%) of AA-192N from Metalor (particles of (A) type), 31 vol.-% (40 wt.-%) of AE9104 from Admatechs (particles of (B) type) and 56 vol.-% (20 wt.-%) of the mixture of components of type (C) and (D) were mixed. Mixing was performed by introducing the mixture of components (C) and (D) into a beaker and then mixing with the further components by means of a spatula, followed by mixing with a paddle mixer at 300 to 400 U/min for 5 min. Thereafter, the mixtures were milled twice in a triple roll mill at 21° C., followed by evacuation at less than 10 mbar under stirring with a paddle mixer for 20 min.

### Example 1b

### Preparation of an Electrically Conductive Composition

A mixture of components of type (C) and (D) was made by mixing 63 pbw of D.E.R.™ 732 from Dow Chemical, 8 pbw of Curezol® C2E4MZ hardener from Shikoku, 23 pbw Araldite® DY-E from Huntsman, 4 pbw of 4-cyclohexanedimethanol divinylether and 2 pbw of oleic acid.

17 vol.-% (50 wt.-%) of SF-3J from Ames Goldsmith (particles of (A) type), 24 vol.-% (30 wt.-%) of CL3000SG from Almatis (particles of (B) type) and 59 vol.-% (20 wt.-%) of the mixture of components of type (C) and (D) were mixed. Mixing was performed by introducing the mixture of components (C) and (D) into a beaker and then mixing with the further components by means of a spatula, followed by mixing with a paddle mixer at 300 to 400 U/min for 5 min. Thereafter, the mixtures were milled twice in a triple roll mill at 21° C., followed by evacuation at less than 10 mbar under stirring with a paddle mixer for 20 min.

### Example 1c

### Preparation of an Electrically Conductive Composition

A mixture of components of type (C) and (D) was made by mixing 69 pbw of D.E.R.™ 732 from Dow Chemical, 4 pbw of 1-(p-methoxybenzyl) tetrahydrothiophenium hexafluoroantimonate, 21 pbw Araldite® DY-E from Huntsman, and 6 pbw of oleic acid.

17 vol.-% (50 wt.-%) of SF-3J from Ames Goldsmith (particles of (A) type), 24 vol.-% (30 wt.-%) of CL3000SG from Almatis (particles of (B) type) and 59 vol.-% (20 wt.-%) of the mixture of components of type (C) and (D) were mixed. Mixing was performed by introducing the mixture of components (C) and (D) into a beaker and then mixing with the further components by means of a spatula, followed by mixing with a paddle mixer at 300 to 400 U/min for 5 min. Thereafter, the mixtures were milled twice in a triple roll mill at 21° C., followed by evacuation at less than 10 mbar under stirring with a paddle mixer for 20 min.

### Example 1d

### Preparation of an Electrically Conductive Composition

A mixture of components of type (C) and (D) was made by mixing 63 pbw of Araldite® PY 302-2 from Huntsman, 8 pbw of Curezol® C2E4MZ from Shikoku, 23 pbw Araldite® DY-E from Huntsman, 4 pbw of 4-cyclohexanedimethanol divinylether and 2 pbw of oleic acid.

13 vol.-% (40 wt.-%) of AA-192N from Metalor (particles of (A) type), 31 vol.-% (40 wt.-%) of AE9104 from Admatechs (particles of (B) type) and 56 vol.-% (20 wt.-%) of the mixture of components of type (C) and (D) were mixed. Mixing was performed by introducing the mixture of components (C) and (D) into a beaker and then mixing with the further components by means of a spatula, followed by mixing with a paddle mixer at 300 to 400 U/min for 5 min. Thereafter, the mixtures were milled twice in a triple roll mill at 21° C., followed by evacuation at less than 10 mbar under stirring with a paddle mixer for 20 min.

### Example 2

### Production of a Photovoltaic Stack

The electrically conductive composition of Example 1 was applied to the backside emitter and collector contacts of a MWT solar cell (JACP6WR-0 from JA Solar) via stencil printing in a thickness of 400 μm.

Meanwhile a punched Ebfoil® dielectric layer from Coveme was placed on a conductive back sheet foil (Ebfoil® Backsheet Back-contact from Coveme) to form a stack. Thereafter, the solar cell was placed with its backside provided with the electrically conductive composition facing the punched Ebfoil® dielectric layer of the stack. On top of the solar cells front side a sheet of a Solar Encapsulant Film EVA9100 from 3M™ was placed. A glass sheet (vsol from vetro solar™) was placed on top of the encapsulant film.

The entire stack was then laminated under application of heat and mechanical pressure. First, temperature was increased to 150° C. at a rate of 13° C./min. At 80° C. a mechanical pressure of 1 bar was applied gently and homogeneously on the top and bottom face of the stack. After 9 minutes at 150° C., the stack was cooled at a rate of 25° C./min until the stack reached 20° C. After reaching 80° C. the mechanical pressure was reduced to zero.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1-14. (canceled)

15. A process for mechanically and electrically connecting a solar cell to an electrical conductor, comprising applying an electrically conductive composition as an electrically conductive adhesive to at least one contact of the solar cell, wherein the at least one contact is selected from the group consisting of emitter contacts and collector contacts, and wherein the electrically conductive composition comprises:
(A) 2 to 35 vol.-% of silver particles having an average particle size in the range of 1 to 25 μm and exhibiting an aspect ratio in the range of 5 to 30:1,
(B) 10 to 63 vol.-% of non-metallic particles having an average particle size in the range of 1 to 25 μm, and exhibiting an aspect ratio in the range of 1 to 3:1,
(C) 30 to 80 vol.-% of a curable resin system, and
(D) 0 to 10 vol.-% of at least one additive,
wherein the sum of the vol.-% of particles (A) and (B) totals 25 to 65 vol.-%.

16. The process according to claim 15, wherein the sum of the vol.-% of (A), (B), (C) and (D) totals 100 vol.-% of the electrically conductive composition.

17. The process according to claim 15, wherein the silver particles (A) are particles of pure silver and/or of silver alloy.

18. The process according to claim 15, wherein the non-metallic particles (B) are selected from the group consisting of graphite particles, glass particles, ceramics particles, plastics particles, diamond particles, boron nitride particles, silicon dioxide particles, silicon nitride particles, silicon carbide particles, aluminosilicate particles, aluminum oxide particles, aluminum nitride particles, zirconium oxide particles and titanium dioxide particles.

19. The process according to claim 15, wherein the silver particles (A) have an average particle size in the range of 0.2 to 2 times the average particle size of the non-metallic particles (B).

20. The process according to claim 15, wherein the curable resin system (C) comprises the constituents of the electrically conductive composition which, after the application and curing thereof, form a covalently crosslinked polymer matrix in which the (A) and (B) particles are embedded.

21. The process according to claim 15, wherein the curable resin system (C) comprises a self-crosslinkable epoxy resin or a system of epoxy resin and hardener for the epoxy resin selected from polyamine hardeners, polycarboxylic acid hardeners and polycarboxylic acid anhydride hardeners.

22. The process according to claim 15, wherein the curable resin system (C) comprises a system of epoxy resin, polyamine hardener for the epoxy resin and optionally a lactone.

23. The process according to claim 15, wherein the electrically conductive composition is applied to at least one contact surface of the electrical conductor to be adhesively bonded to the solar cell.

24. The process according to claim 23, wherein the application of the electrically conductive composition is performed by printing, jetting or dispensing.

25. The process according to claim 24, wherein after the application of the electrically conductive composition, the at least one solar cell contacts and the electrical conductor(s) to be adhesively bonded thereto are put together with their contact surfaces having the electrically conductive composition in between to form an assembly.

26. The process according to claim 25, wherein the electrically conductive composition in the assembly is cured.

27. The process according to claim 26, wherein the curing is thermal curing.

28. The process according to claim 27, wherein the thermal curing is performed in a separate step in the course of assembling and consolidating a photovoltaic stack.
